(19) United States
(12) Patent Application Publication
(10) Pub. No.: US 2025/0140780 A1
(43) Pub. Date: May 1, 2025

(54) PROCESSING PVD-DEPOSITED ANODE ASSEMBLIES

(71) Applicant: LI-METAL CORP., Markham (CA)

(72) Inventors: Maciej JASTRZEBSKI, Markham (CA); Kristyn M. ZOSCHKE, Markham (CA); Jonathan T. GOODMAN, Markham (CA)

(73) Assignee: LI-METAL CORP., Markham, ON (CA)

(21) Appl. No.: 18/837,345

(22) PCT Filed: Feb. 10, 2023
(86) PCT No.: PCT/CA2023/050172

§ 371 Date: Aug. 9, 2024

Related U.S. Application Data
(60) Provisional application No. 63/309,390, filed on Feb. 11, 2022.

(51) Int. Cl. H01M 4/04; C23C 14/14; C23C 14/24; H01M 4/02; H01M 4/38

(52) U.S. Cl. CPC H01M 4/0423; C23C 14/14; C23C 14/24; H01M 4/0435; H01M 4/382; H01M 2004/021; H01M 2004/027

(57) ABSTRACT

Herein are described processes for and machines adapted for the production of lithium coated conductive substrates having conductive substrate planar surfaces. The process can include providing a lithium coated conductive substrate and then calendering the coated-foil to provide the desired planar surface(s). In a preferable instance, the process provides double sided lithium carrying conducive substrates useful in lithium metal batteries. In another instance, the process provides single or double sided coated-foils carrying polymeric sheets. The machines for the production of the desired products preferably include apparatus for the deposition of lithium metal onto a conductive substrate and one or more calendering systems, preferable within a single vacuum chamber.

### CROSS-REFERENCE TO RELATED APPLICATIONS

This disclosure claims the benefit of priority to U.S. Patent Application No. 63/309,390, filed Feb. 11, 2022, the entirety of which are incorporated herein.

### FIELD OF THE INVENTION

The present disclosure relates generally to a system and process for processing multi-layer anode assemblies that include a layer of reactive material (such as lithium) that has been deposited on a suitable carrier web/substrate via a physical vapour deposition process, including specifically calendering the multi-layer anode assemblies before exposing the pvd-deposited reactive material to potential contaminants like oxygen and nitrogen.

### BACKGROUND

International patent publication no. WO 2021/080052 discloses a lithium metal anode structure, an electrochemical device comprising same, and a method for manufacturing the lithium metal anode structure. The lithium metal anode structure comprises: a lithium metal anode; and a separator attached to at least one surface of the lithium metal anode, the separator comprising: a porous substrate; and an inorganic layer coated on the porous substrate and containing inorganic nanoparticles with a size of 5-200 nm, wherein the inorganic layer is disposed between the lithium metal anode and the porous substrate. The lithium metal anode structure may be manufactured using a rolling roll or press, so that the surface of the lithium metal anode can be made uniform and the sealing between the inorganic layer and the lithium metal anode can be improved, thereby suppressing the growth of lithium dendrites and minimizing the reaction of lithium during the life cycle.

U.S. Pat. No. 10,862,171 discloses methods for making solid-state laminate electrode assemblies include methods to prevent devitrifying and damaging a lithium ion conducting sulfide glass substrate during thermal evaporation of lithium metal, as well as methods for making thin extruded lithium metal foils.

U.S. patent publication no. US 2020/0280104 discloses anode subassembly sheets that include a lithium-metal layer sandwiched between a pair of separator layers to ease handling of the lithium metal to promote fast and efficient stacked-jellyroll assembly. In some embodiments, the separator layers are pressure laminated to the lithium-metal layer without any bonding agent. In some embodiments, a stacked jellyroll is made by alternatingly stacking anode subassembly sheets with cathode sheets. In some embodiments, a functional coating beneficial to the lithium-metal layer is provided to one or more separator layers prior to laminating the separator(s) to the lithium metal layer. Lithium-metal batteries made using stacked jellyrolls made in accordance with aspects of the disclosure are also described.

Japanese patent publication no. JP2797390B2 discloses a negative electrode and a carbonaceous material and a current collector as an anode active material, a positive electrode having a lithium compound as a positive electrode active material, a secondary battery and a nonaqueous electrolyte, the positive electrode active material, the second having a main active material composed of a first lithium compound having a nobler potential than the oxidation potential of the current collector, a lower potential than the oxidation potential of the collector. By including a subsidiary active substance consisting of lithium compound, it is obtained so as to have excellent properties against over-discharge.

U.S. Pat. No. 10,177,366 discloses a high purity lithium and associated products. In a general embodiment, the present disclosure provides a lithium metal product in which the lithium metal is obtained using a selective lithium ion conducting layer. The selective lithium ion conducting layer includes an active metal ion conducting glass or glass ceramic that conducts only lithium ions. The present lithium metal products produced using a selective lithium ion conducting layer advantageously provide for improved lithium purity when compared to commercial lithium metal. Pursuant to the present disclosure, lithium metal having a purity of at least 99.96 weight percent on a metals basis can be obtained.

### SUMMARY

A first embodiment is a process that includes providing a coated-foil that features a lithium layer carried on a conductive substrate, the lithium layer having a convex transverse surface; and calendering the coated-foil thereby converting the convex transverse surface to a conductive substrate-planar transverse surface.

A second embodiment is a machine for the production of a double-sided lithium coated-foil having a first conductive substrate-planar transverse surface and an opposing side, second conductive substrate-planar transverse surface, the machine includes a vacuum chamber that features a deposition apparatus adapted to deposit lithium metal onto a web of a conductive substrate, a drum adapted to carry and cool the web of the conductive substrate after and/or during the disposition of the lithium metal, a calendering unit adapted to convert a convex transverse surface of a lithium layer carried on the conductive substrate to a conductive substrate-planar transverse surface.

### BRIEF DESCRIPTION OF THE FIGURES

For a more complete understanding of the disclosure, reference should be made to the following detailed description and accompanying drawing figures wherein:

FIG. 1 is a schematic representation of the affect of the herein disclosed process on a lithium coated conductive substrate;

FIG. 2 is a schematic representation of the herein disclosed process;

FIG. 3 is a second schematic representation of the herein disclosed process;

FIG. 4 is a schematic representation of the effect of the herein disclosed process on the shape and structure of the lithium coated conductive substrate;

FIG. 5 is a third schematic representation of the herein disclosed process wherein a polymeric sheet is adhered to the surface of the lithium coated conductive substrate;

FIG. 6 is a schematic representation of the effect of the herein disclosed process on the shape and structure of the lithium coated conductive substrate when carrying a polymeric sheet;

FIG. 7 is a depiction of a machine for the production of the herein described lithium coated conductive substrate; and

FIG. 8 is a depiction of a machine for the production of the herein described polymer carrying lithium coated conductive substrate.

While specific embodiments are illustrated in the figures, with the understanding that the disclosure is intended to be illustrative, these embodiments are not intended to limit the invention described and illustrated herein.

### DETAILED DESCRIPTION

Objects, features, and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

Herein, the use of the word “a” or “an” when used in conjunction with the term “comprising” in the claims and/or the specification may mean “one,” but it is also consistent with the meaning of “one or more,” “at least one,” and “one or more than one.” The term “about” means, in general, the stated value plus or minus 5%. The use of the term “or” in the claims is used to mean “and/or” unless explicitly indicated to refer to alternatives only or the alternative are mutually exclusive, although the disclosure supports a definition that refers to only alternatives and “and/or.”

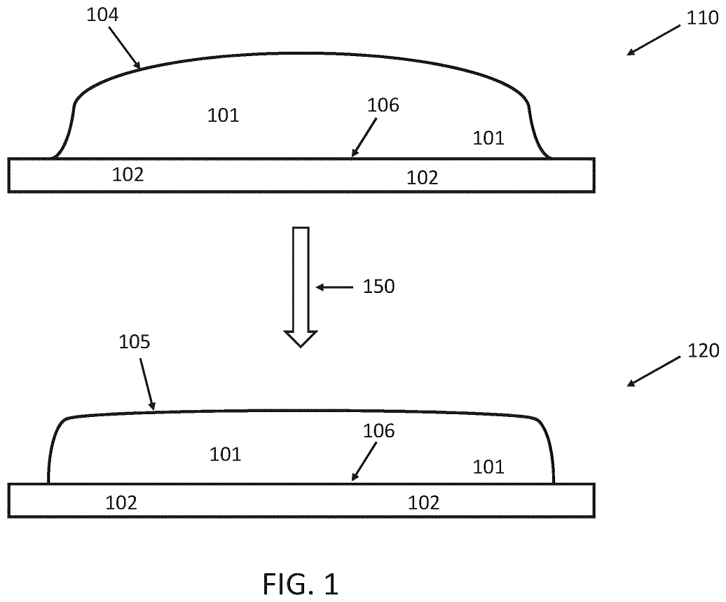

Herein, the processes and machines described relate generally to affecting the shape and surface of a lithium metal coating on a current collector (e.g., copper foil). Preferably, the process and machines impart a superior surface for the use of the lithium metal in a cell or battery. Accordingly and in reference to FIG. 1, a first embodiment is a process that includes providing a coated-foil 110 that includes a lithium layer 101 carried on a conductive substrate 102 and calendering 150 the coated-foil 110 to provide a calendered coated-foil 120. In a preferably instance, the lithium layer 101 initially includes a convex transverse surface 104, and more preferably has a consistent longitudinal surface. The calendering 150 thereby converts the convex transverse surface 104 to a conductive substrate-planar transverse surface 105. As used herein, the term conductive substrate-planar transverse surface should be understood to mean that the surface of the lithium layer carried on the conductive substrate, after calendering, is planar to and/or parallel with the surface 106 of the conductive substrate 102 adjacent to the lithium layer 101.

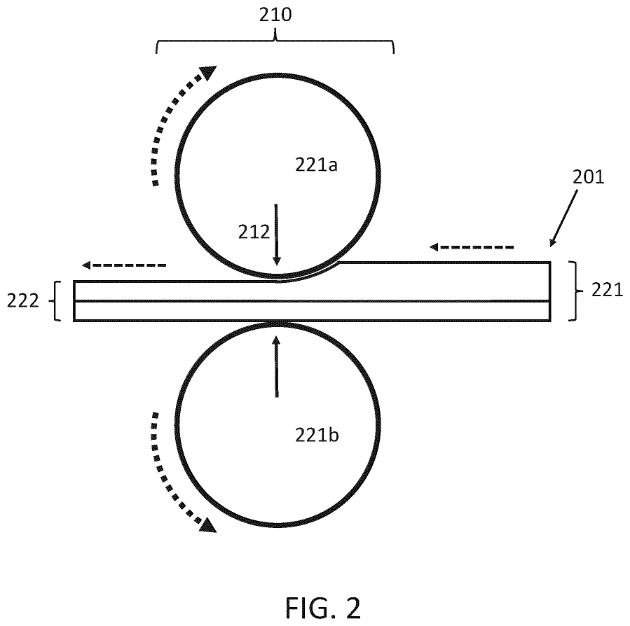

In one instance shown in FIG. 2, the process includes passing the coated-foil 201 through a calendering system 210 that can include one or more calendering rollers (e.g., 221a & 211b). In a preferable example, the calendering system 210 includes two calendering rollers (221a & 211b) that affect the surface of the coated-foil 201. The calendering system 210 can be gapped and/or weighted wherein two calendering rollers can be positioned with a fixed gap 212 between the rollers and/or the two calendering rollers could impart a fixed pressure/force upon the coated-foil as it passes therebetween. In another preferable example, the calendering system 210 reduces a provided thickness 221 of the coated-foil 201 and thereby provides the coated-foil 201 with a calendered thickness 222 that is less than the provided thickness 221.

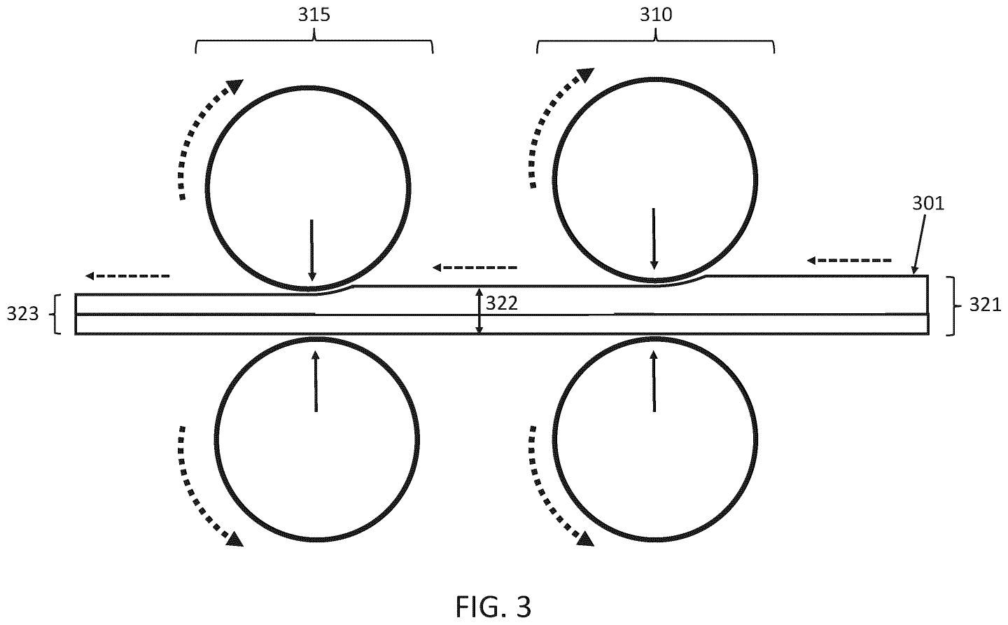

Another instance, as shown in FIG. 3, includes passing the coated-foil 301 through a first calendering system 310 and then a second calendering system 315. In a preferable example, the sequential calendering systems reduce a coated-foil thickness 321 to a first calendered thickness 322 then then to a second calendered thickness 323.

The sequential calendering systems can be gapped and/or weighted, for example, wherein two calendering rollers can be positioned with a fixed gap between the rollers and/or the two calendering rollers could impart a fixed pressure/force upon the coated-foil as it passes therebetween. In one example, the first and the second calendering systems each have a fixed gap, wherein the second calendering system has a gap that is smaller than the first calendering system. In another example, the first and the second calendering systems are both weighted. In still another example, one of the first and the second calendering systems have a fixed gap and the other is weighted. In still yet another example, one of the first and the second calendering systems is patterned and imparts a texture or pattern to the surface of the lithium layer. In a more preferable example, the first calendering roller has a first fixed gap, and the second calendering roller has a second fixed gap; wherein the first fixed gap is greater than then second fixed gap by at least about 0.05, 0.1, 0.2, 0.3, 0.4, 0.5, 0.6, 0.7, 0.8, 0.9, 1, 1.1, 1.2, 1.3, 1.4, or 1.5 μm. In a still more preferable example, the first calendering roller has a first nip pressure, and the second calendering roller has a second nip pressure. The nip pressures can be the same, the first nip pressure can be higher than the second nip pressure, or the second nip pressure can be higher than the first nip pressure. In any example, the nip pressures are preferably between about 0.5 megapascal (MPa) and about 10 MPa, about 0.5 to about 7.5 MPa, about 0.5 to about 5 MPa, about 1 to about 5 MPa, or about 0.5 MPa, about 1 MPa, about 2 MPa, about 3 MPa, about 4 MPa, about 5 MPa, about 6 MPa, about 7 MPa, about 8 MPa, about 9 MPa, or about 10 MPa. In a specific example, the first nip pressure is between about 0.5 and 5 MPa and the second nip pressure is between about 0.5 and 5 MPa.

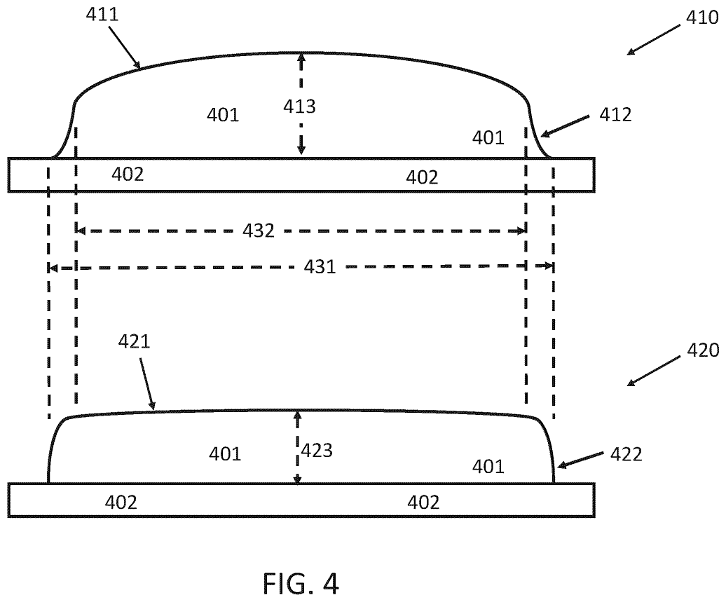

Referring now to FIG. 4, the lithium layer 401 on the provided coated-foil 410 and/or the calendered coated-foil 420 preferably has a thickness (413 and/or 423) that is less than about 100, 90, 80, 70, 60, 50, 40, 30, 20, or 10 μm. In a more preferably instance, the provided thickness 413 and the calendered thickness 423 are each less than about 40, 30, 20, or 10 μm. Notably, the provided thickness 413 is determined at the maximum thickness which is typically centered transversely on the coated-foil. In a particularly preferable instance, the provided coated-foil 410 is prepared by the deposition of lithium (as a lithium layer 401) onto the conductive substrate 402, more preferably the lithium deposition is a physical deposition (PVD) of lithium metal onto the conductive substrate, for example by condensation of lithium vapor. In another instance, the convex transverse surface includes a convex maximum thickness (a provided thickness), the conductive substrate-planar transverse surface includes a planar thickness (a calendered thickness), and the difference between the convex maximum thickness and the planar thickness is less than about 10, 9, 8, 7, 6, 5, 4, 3, 2, or 1 μm. In a preferable instance, the difference is less than about 2.5 μm. In another example, the calendered thickness (the planar thickness) is about 95, 90, 85, 80, 75, 70, 65, 60, 55, or 50% of the provided thickness (the convex maximum thickness). The calendered thickness can alternatively be about 45 to about 95, about 55 to about 95, about 65 to about 95, about 75 to about 95, about 85 to about 95 percent of the convex maximum thickness. Accordingly, the process reduces the thickness of the lithium layer from the provided lithium layer (the convex maximum thickness) to the calendered lithium layer (the planar thickness) by about 5 to about 45, about 5 to about 40, about 5 to about 35, about 5 to about 30, about 5 to about 25, about 5 to about 20 about 5 to about 15 percent.

Notably, the PVD deposition of lithium onto the conductive substrate provides a lithium layer 401 having a convex transverse surface 411 that includes, consists essentially of, or consists of lithium metal. The herein describes process preferably converts the convex transverse surface 411 to a conductive substrate-planar transverse surface 421. Additionally, the herein described process can affect the width of the convex transverse surface 411 and conductive substrate-planar transverse surface 421. In the provided coated-foil 410, the convex transverse surface 411 often has a (transverse) width 432 that is less than the total “lithium wetted” surface width 431 of the conductive substrate 402. Preferably, the calendered coated-foil 420 includes a transverse surface 421 that has a (transverse) width 431 that is about the same as the total “lithium wetted” surface. In some instances, the provided coated-foil 410 has a concave provided-lithium layer edge surface 412 whereas the calendered coated-foil 410 has a convex calendered-lithium layer edge surface 422. In a preferable instance, the calendered coated-foil 420 has a vertical calendered-lithium layer edge surface 422, that is, the edge surface is perpendicular to the transverse surface 421.

In yet another instance, the (provided) convex transverse surface 411 has a Roughness (Ra value greater than about 0.5, 0.6, 0.7, 0.8, 0.9, or 1 μm and the process described herein flattens or smooths the surface. Accordingly, the conductive substrate-planar transverse surface 421, preferably, includes a Ra value of less than about 0.4, 0.3, 0.2, or 0.1 μm. In yet another instance, the (provided) convex transverse surface 411 has a Roughness (Rz) value greater than about 5, 6, 7, 8, 9, or 10 μm and the process described herein flattens or smooths the surface. Accordingly, the conductive substrate-planar transverse surface 421, preferably, includes a Rz value of less than about 4, 3, 2, or 1 μm.

The (provided) convex transverse surface 411 can have a coherent or relatively smooth and undimpled surface, whereas the herein described process can imprint micro and/or nanocavities on the lithium layer. In one example, a calendering roller in contact with the lithium surface includes a plurality of raised projections that deform or imprint their shapes onto/into the lithium surface. Accordingly, micro and/or nanocavities can be printed into the lithium thereby affecting the surface chemistry of the resulting material.

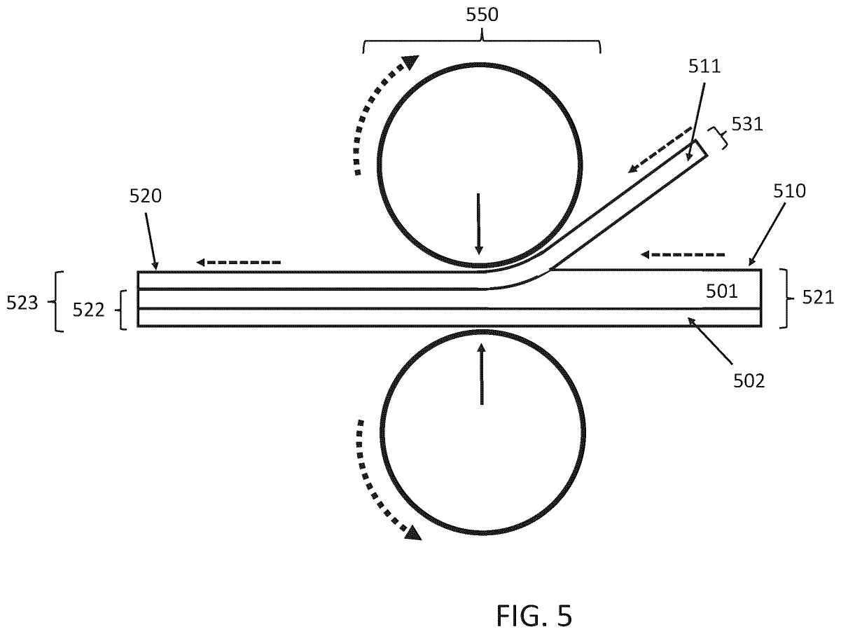

The process can further include laminating a polymeric sheet to the lithium layer. As shown in FIG. 5, process includes providing a coated-foil 510 that includes a lithium layer 501 carried on a conductive substrate 502, providing a polymeric sheet 511, and calendering the polymeric sheet 511 adjacent to the lithium layer 501 on the coated-foil 510 via a calendering system 550. In a preferable instance, the polymeric sheet 511 is mechanically adhered to the lithium layer 501. The mechanical adhesion of the polymer sheet and the lithium layer can be through the plastic deformation of the lithium and interpenetration of the lithium metal with a porous structure of the polymer sheet. Accordingly, in one example the polymer sheet is a porous polymeric sheet, for example a polymeric separator. The provided coated-foil 510 has a thickness 521 that can be reduced via the calendering system 550 thereby providing a calendered thickness 522 that is less than that of the provided thickness 521. In one example, the polymer thickness 531 is not reduced via calendering 550; whereas in another example, the polymer thickness may be reduced. Notably, the sum of the polymer thickness 531 and the provided coated-foil thickness 521 is greater than the polymer-containing calendered foil 520 thickness 523.

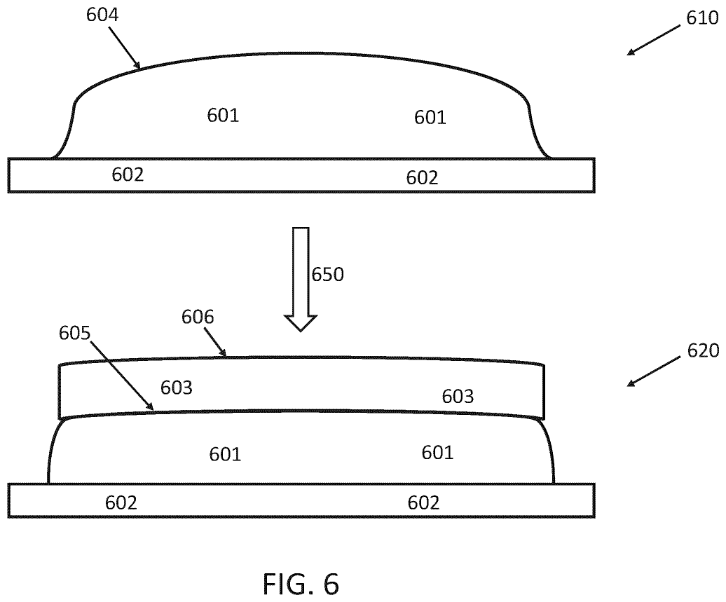

Viewed via a transverse cross-section in FIG. 6, the coated foil 610 includes a lithium layer 601 carried on and adhered to a conductive substrate 602 and has a convex transverse surface 604. The calendering process 650 both mechanically adheres a polymeric sheet 603 to the lithium layer 601 and converts the convex transverse surface 604 to a conductive substrate-planar transverse surface 605 which carries and is adhered to the polymer sheet 603 thereby providing a polymer carrying calendered coated-foil 620. Preferably, the polymeric sheet 603 further includes a conductive substrate-planar transverse surface 606. That is, the calendering process 650 preferably flattens the lithium layer and delivers a product that has a lithium layer with a uniform transverse thickness (e.g., having a planar transverse surface 605) and a polymeric layer (sheet) 603 with a uniform transverse thickness and a planar transverse surface 606.

In another instance, the process of providing the coated-foil includes depositing lithium metal onto the conductive substrate via a physical vapor deposition (PVD) process and thereafter calendering the coated-foil. Preferably, the PVD process is a roll-to-roll process where lithium is deposited onto the conductive substrate through the condensation of lithium vapor in a vacuum. The process can further include depositing lithium metal onto an opposing side of the conductive substrate via a PVD process thereby forming a double-sided coated-foil and thereafter calendering the double-sided coated-foil. Notably, the first PVD deposited lithium layer can be calendered prior to the deposition of the lithium metal onto the opposing side, alternatively, lithium metal can be deposited onto the opposing side of the first PVD deposited lithium layer and then both sides are calendered at once.

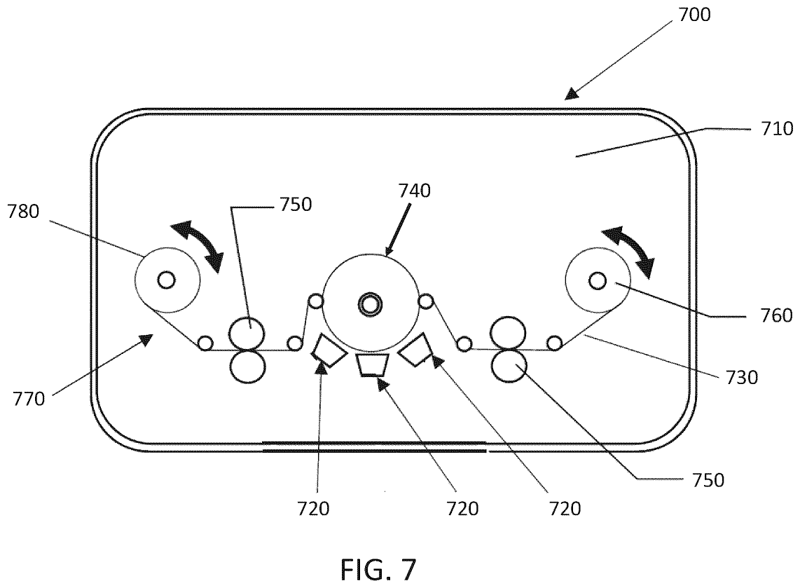

Another embodiment is a machine adapted to the production of a lithium coated foil, preferably to the production of a double-sided lithium coated-foil having a first conductive substrate-planar transverse surface and on an opposing side, a second conductive substrate-planar transverse surface. In a first instance depicted in FIG. 7, the machine 700 can feature a vacuum chamber 710 that includes and is therein arranged a deposition apparatus 720 or a plurality of deposition apparatus (each 720) adapted to deposit lithium metal onto a web of a conductive substrate 730, a drum 740 adapted to carry and cool the web of the conductive substrate 730 after and/or during the disposition of the lithium metal, a calendering unit 750 adapted to convert a convex transverse surface of a lithium layer carried on the conductive substrate to a conductive substrate-planar transverse surface. The machine 700 can further include a feed roller 760 adapted to deliver the web of conductive substrate 730 from a coil through rollers (e.g., 750) to the drum 740 through which the web is carried past the deposition apparatus 720. The coated web is then carried through a calendering unit 750 delivering the calendered coated-foil 770 which can be coiled on a collection roller 780. Notably and as shown in FIG. 7, the machine can be run from the feed roller 760 to the collection roller 780 and/or alternatively in reverse from the feed roller nee collection roller 780 to the collection roller neé feed roller 760. Accordingly, multiple depositions can be sequentially provided upon the web of conductive substrate.

The vacuum chamber can further include multiple drums and deposition apparatus for sequentially coating a first side and a second side of the web of conductive substrate. Specifically, the vacuum chamber can further include a second deposition apparatus adapted to deposit lithium metal onto an opposing side of the conductive substrate. The vacuum chamber can further feature a second drum adapted to carry and cool the web of a conductive substrate after and/or during the second disposition of the lithium metal. In instances where lithium is deposited onto a first and a second surface of the conductive substrate, the machine can include one or more calendering units. In a first example, the lithium carried on the first side and the second side of the conductive substrate can be co-calendered or contemporaneously calendered through the use of a single calendering unit that is adapted to affect the convex surfaces on each side of the coated-foil. In another example, the lithium carried on the first side can pass through a calendering unit, lithium can be deposited on a second side, and then this coated-foil, preferably with a first planar surface and a second convex surface can pass through a calendering unit whereby the second convex surface is converted to a second planar surface. Still further the machine can include a plurality of sequential calendaring units as necessary to achieve the desired planar surface and any surface features. For example, the machine can include a vacuum chamber that features a second calendering unit adapted to convert a second convex transverse surface of a second lithium layer carried on the opposing side of the conductive substrate to a second conductive substrate-planar transverse surface.

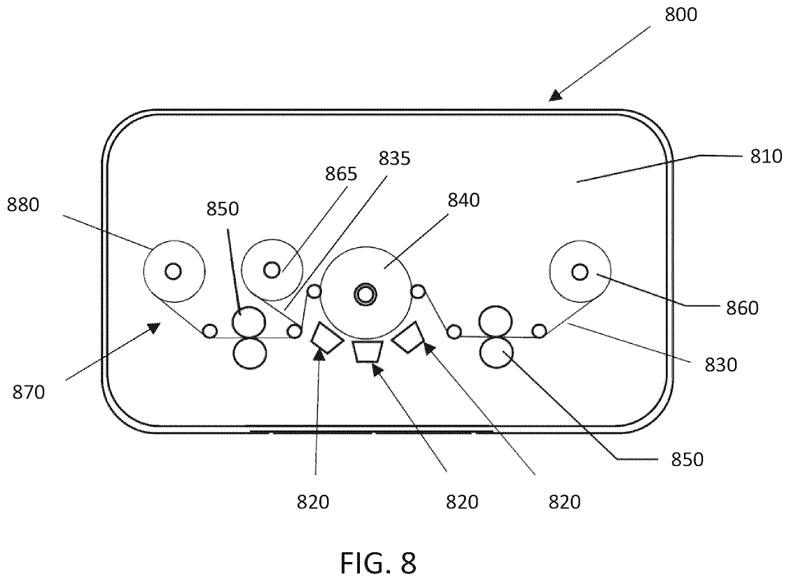

In still another instance, as depicted in FIG. 8, the machine 800 can include a polymer feed roller 865 adapted to deliver a polymeric sheet 835 to a lithium surface. That is, the machine 800 can feature a vacuum chamber 810 that includes and is therein arranged a deposition apparatus 820 or a plurality of deposition apparatus (each 820) adapted to deposit lithium metal onto a web of a conductive substrate 830, a drum 840 adapted to carry and cool the web of the conductive substrate after and/or during the disposition of the lithium metal. Thereafter the deposition of lithium, the machine is adapted to deliver from a polymer feed roller 865, a polymeric sheet 835 to the deposited lithium carried on the conductive substrate. The machine then can feature one or move calendering units 850 adapted to convert a convex transverse surface of a lithium layer carried on the conductive substrate to a conductive substrate-planar transverse surface.

In a preferred instance, the polymeric sheet and the lithium surface are physically adhered by the application of pressure to the polymeric sheet carried on the lithium surface. The polymeric sheet and lithium can be adhered by the calendaring unit 850. Specifically, where the calendering unit 850 is adapted to laminate the polymeric sheet 835 to the lithium layer.

In one example, the calendering unit 850 is adapted to both laminate the polymeric sheet to the lithium layer and affect the shape of the lithium layer surface. In another example (not shown), the machine can include a first calendering unit adapted to affect the shape of the lithium layer surface and a second calendering unit adapted to laminate the polymeric sheet to the lithium layer. The machine 800 can further include a feed roller 860 adapted to deliver the web of conductive substrate 830 from a coil through rollers (e.g., 850) to the drum 840 through which the web is carried past the deposition apparatus 820. The polymeric sheet 835 is then applied to the deposited lithium then the composite web is carried through a calendering unit 850 delivering the polymer-carrying calendered coated-foil 870 which can be coiled on a collection roller 880.

In a preferential instance, the vacuum chamber can further include multiple drums and deposition apparatus for sequentially coating a first side and a second side of the web of conductive substrate with lithium and then the polymeric sheet. Specifically, the vacuum chamber can include a first deposition apparatus adapted to deposit lithium metal onto a first side of the conductive substrate and includes a second deposition apparatus adapted to deposit lithium metal onto an opposing side (as second side) of the conductive substrate. In this instance, the vacuum chamber preferably features a second drum adapted to carry and cool the web of a conductive substrate after and/or during the second disposition of the lithium metal. In instances where lithium is deposited onto a first and a second surface of the conductive substrate, the machine can include one or more polymer feed rollers and one or more calendering units. In a first example, polymeric sheets can be deposited onto the lithium carried on the first side and the second side of the conductive substrate and thereafter this multilayer material (having a polymeric sheet, a lithium layer, a conductive substrate, a second lithium layer, and a second polymeric sheet) can be co-calendered or contemporaneously calendered through the use of a single calendering unit that is adapted to affect the convex surfaces on each side of the coated-foil. Still further the machine can include a plurality of sequential calendaring units as necessary to achieve the desired planar surface and any surface features. For example, the machine can include a vacuum chamber that features a second calendering unit adapted to convert a second convex transverse surface of a second lithium layer carried on the opposing side of the conductive substrate to a second conductive substrate-planar transverse surface. In still another instance, the machine and process can be adapted so the first and second lithium layers can be calendered prior to the deposition of the polymeric sheet(s) and, optionally, wherein the first and second lithium layers can be textured prior to the deposition of the polymeric sheet(s).

In a still more preferable instance, the first and the second sides of the conductive substrate are coated with lithium and calendering in a single vacuum chamber without breaking the vacuum. In this instance, the vacuum chamber can include a plurality of drums and a plurality of deposition apparatus. In a less preferable instance, the vacuum chamber can include a single drum but wherein the machine is adapted to collect the single-sided lithium coated conductive substrate on a collection roller and then feed the conductive substrate back to the drum and deposition apparatus through a plurality of rollers adapted to deliver lithium to the uncoated side of the conductive substrate. In yet another, less preferable instance, the machine and process can include a vacuum chamber with a single drum wherein coating the second side of the conductive substrate requires the removal of the single-sided coated-foil and then reinsertion into the machine such that the uncoated side of the conductive substrate can be coated with lithium. In still yet another instance, the second deposition can be accomplished in a second vacuum chamber that, optionally, is separated from a first vacuum chamber by one or a series of separation seals.

While the compositions and methods of this invention have been described in terms of preferred embodiments, it will be apparent to those of skill in the art that variations may be applied to the compositions and/or methods in the steps or in the sequence of steps of the method described herein without departing from the concept, spirit and scope of the invention. More specifically, it will be apparent that certain agents that are both chemically and physically related may be substituted for the agents described herein while the same or similar results would be achieved. All such similar substitutes and modifications apparent to those skilled in the art are deemed to be within the spirit, scope and concept of the invention as defined by the appended claims.

1. A process comprising:
providing a coated-foil that includes a lithium layer carried on a conductive substrate, the lithium layer having a convex transverse surface;
calendering the coated-foil thereby converting the convex transverse surface to a conductive substrate-planar transverse surface.

2. The process of claim 1, wherein the lithium layer has a thickness of less than 30 μm.

3. The process of claim 1, wherein the convex transverse surface consists essentially of lithium metal.

4. The process of claim 1, wherein the convex transverse surface includes a Roughness (Ra) value greater than about 0.5 μm and wherein the conductive substrate-planar transverse surface includes a Ra value of less than about 0.4 μm.

5. The process of claim 1, wherein calendering the coated-foil includes imprinting micro and/or nanocavities on the lithium layer.

6. The process of claim 1, wherein calendering the coated-foil includes passing the coated foil through a first calendering system and a second calendering system.

7. The process of claim 6, wherein the first calendering system has a first fixed gap, and the second calendering system has a second fixed gap; wherein the first fixed gap is greater than then second fixed gap by at least about 0.2 μm.

8. The process of claim 6, wherein the first calendering system has a first nip pressure, and the second calendering system has a second nip pressure.

9. The process of claim 8, wherein the first nip pressure is between about 0.5 and 10 megapascals (MPa); and wherein the second nip pressure is between about 0.5 and 10 MPa.

10. The process of claim 1, wherein the convex transverse surface includes a convex maximum thickness; wherein the conductive substrate-planar transverse surface includes a planar thickness; and wherein a difference between the convex maximum thickness and the planar thickness is less than 5 μm.

11. The process of claim 10, wherein the difference is less than about 2.5 μm.

12. The process of claim 1, wherein calendering the coated-foil includes laminating a polymeric sheet to the lithium layer.

13. The process of claim 12, wherein the polymeric sheet is mechanically adhered to the lithium layer.

14. The process of claim 1, wherein providing the coated-foil includes depositing lithium metal onto the conductive substrate via a PVD process and thereafter calendering the coated-foil.

15. The process of claim 14 further comprising depositing lithium metal onto an opposing side of the conductive substrate via a PVD process thereby forming a double-sided coated-foil and thereafter calendering the double-sided coated-foil.

16. A machine for the production of a double-sided lithium coated-foil having a first conductive substrate-planar transverse surface and on an opposing side, a second conductive substrate-planar transverse surface, the machine comprising:
a vacuum chamber that includes
a deposition apparatus adapted to deposit lithium metal onto a web of a conductive substrate,
a drum adapted to carry and cool the web of the conductive substrate after and/or during the disposition of the lithium metal, and
a calendering unit adapted to convert a convex transverse surface of a lithium layer carried on the conductive substrate to a conductive substrate-planar transverse surface.

17. The machine of claim 16, wherein the vacuum chamber further includes a second deposition apparatus adapted to deposit lithium metal onto the opposing side of the conductive substrate;
a second drum adapted to carry and cool the web of a conductive substrate after and/or during the second disposition of the lithium metal.

18. The machine of claim 16, wherein the vacuum chamber further includes a second calendering unit adapted to convert a second convex transverse surface of a second lithium layer carried on the opposing side of the conductive substrate to the second conductive substrate-planar transverse surface.

19. The machine of claim 16, wherein the calendering unit is further adapted to laminate a polymeric sheet to the lithium layer.
